(19) United States
(12) Patent Application Publication
(10) Pub. No.: US 2007/0262442 A1
(43) Pub. Date: Nov. 15, 2007

(54) Packaged electronic component

(75) Inventors: Chih-Tse Chen, Taoyuan Hsien (TW); Ching-Man Kao, Taoyuan Hsien (TW); Han-Cheng Hsu, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/518,149

(22) Filed: Sep. 11, 2006

(30) Foreign Application Priority Data
May 11, 2006 (TW) 95116695

(51) Int. Cl. H01L 23/34

(52) U.S. Cl. 257/706

(57) ABSTRACT

A packaged electronic component includes a body, a plurality of magnetic elements and a silicon material, wherein the magnetic elements are disposed in the body, and the silicon material covers the surfaces of the magnetic elements. At least one side of the body has a hole to dissipate heat, and provides additional space to contain expanded silicon material after heating.

### BACKGROUND OF THE INVENTION

1. Field of the Invention

The invention relates to a packaged electronic components, and in particular, to a packaged electronic component having at least one hole for heat dissipation.

2. Description of the Related Art

Protecting the environment is essential for the quality of life and future generations. Thus, according to European Union environmental policy, soldering process now prohibits the usage of lead because lead not only endangers the environment, but also presents a serious health hazard. After research, some lead-free soldering materials have become acceptable usable, such as tin-silver-copper alloy.

Referring to FIG. 1, a conventional packaged electronic component 1 is a Surface Mount Device (SMD). During reflow soldering, a light source 12 heats the soldering material by infrared irradiation. Using tin-lead alloy as a conventional soldering material, infrared temperatures are about 200° C., sufficient to melt the solder material. For lead-free material, such as tin-silver-copper alloy, melting temperatures of infrared must reach about 260° C.

Referring to FIG. 2A, at least one coil 112 is disposed in the body 11 of the packaged electronic component 1 and the surface of the coil 112 is covered by a silicon material 113. When the body 11 is at 260° C. during reflow soldering, the silicon material 113 in the body 11 expands due to high temperature. The stress of the silicon material 113 is transmitted to the body 11, on which cracks 114 are produced, (as shown in FIG. 2B), decreasing reliability.

Thus, packaged electronic components suited to lead-free process, maintaining the integrity of the body thereof, are called for.

### BRIEF SUMMARY OF THE INVENTION

The invention provides a packaged electronic component, suitable to lead-free process without resulting in cracks.

The packaged electronic component comprises a body, a plurality of magnetic elements disposed in the body, and a silicon material covering the surfaces of the magnetic elements, wherein the body is formed by a molding material, and at least one side of the body has at least one hole.

As described above, because the hole is formed on the side of the body, heat is efficiently dissipated through the hole during high-temperature reflow soldering. Additionally, extra space is provided for the heated silicon material. Compared to the prior art, the packaged electronic component of the invention lowers the temperature transmitted to the silicon material and creates space to contain the heated silicon material, such that the body of the packaged electronic component will not crack due to the thermal expansion of the silicon material.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic view of a conventional packaged electronic component during reflow soldering;

FIG. 2A is a sectional view of a conventional packaged electronic component during reflow soldering;

FIG. 2B is a schematic view of the conventional packaged electronic component in FIG. 2A with a crack;

FIG. 3 is a schematic view of a packaged electronic component of an embodiment without silicon material; and

FIG. 4 is a sectional view of the packaged electronic component in FIG. 3 with silicon material.

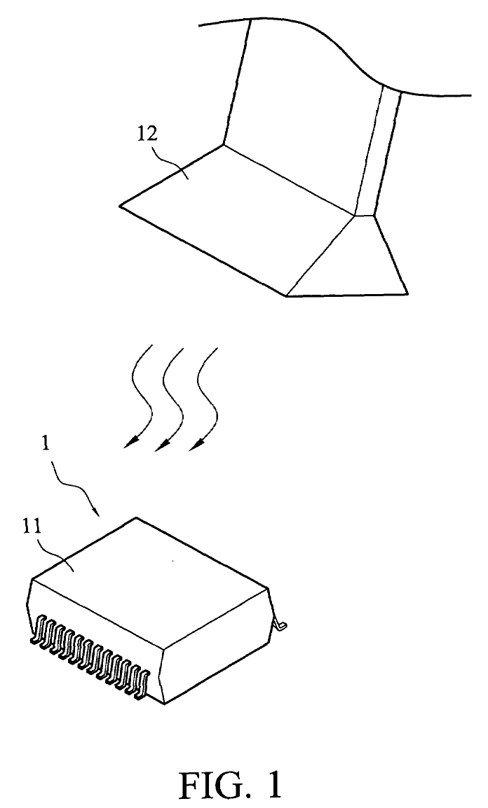

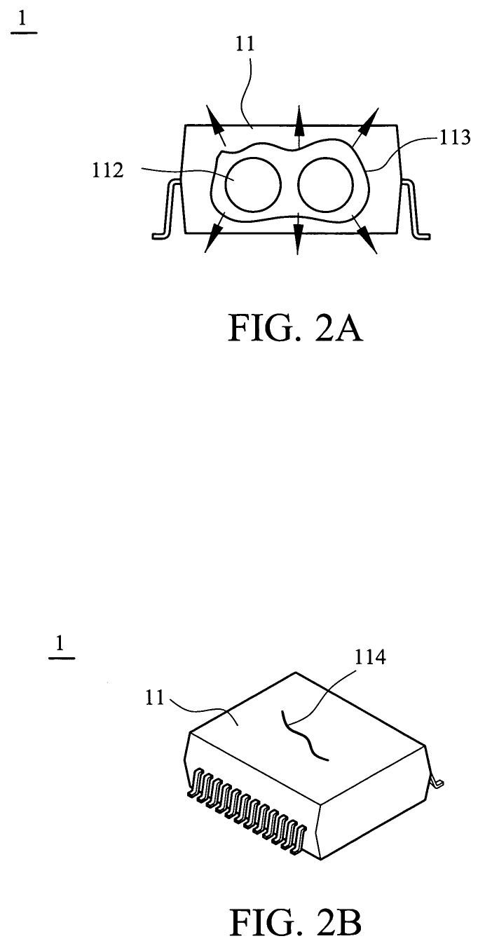

### DETAILED DESCRIPTION OF THE INVENTION

A preferred embodiment of the invention provides a packaged electronic component, wherein same elements are referenced with the same number in the relevant figures.

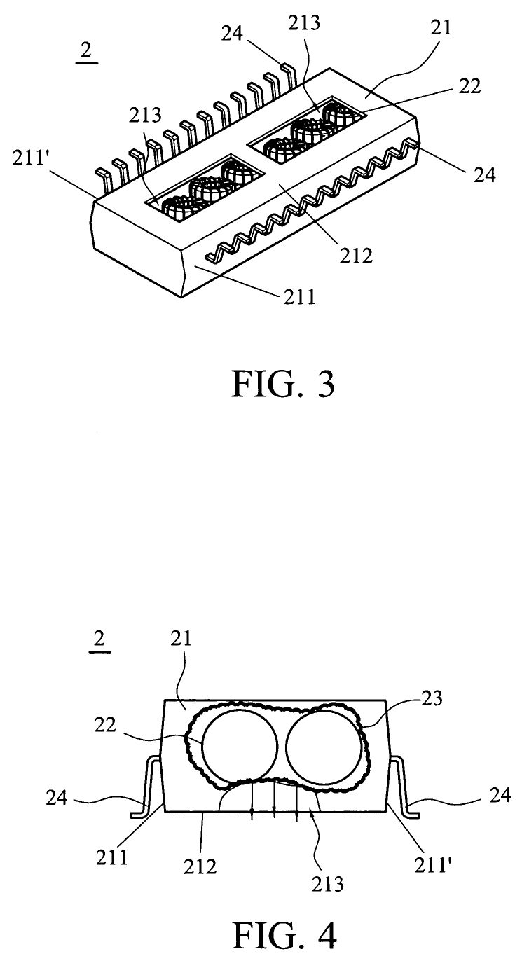

Referring to FIGS. 3 and 4, the packaged electronic component 2 comprises a body 21, a plurality of magnetic elements 22, a silicon material 23, and a plurality of pins 24.

The body 21 is made of molding material, covering the magnetic elements 22. In the embodiment, the magnetic elements are coils, and the molding material comprises epoxy resin. As shown in FIG. 3, the silicon material 23 covers surfaces of the magnetic elements 33 (to clearly show the coils in FIG. 4, silicon material 23 is omitted here) to protect the magnetic elements 22. The pins 24 are disposed on two opposite sides 211, 211′ of the body 21, electrically connecting other electronic components or apparatus. The packaged electronic component 2 is preferably a surface mount device (SMD), such as a LAN filter.

A side 212 of the body 21 has at least one hole 213. In this embodiment, two holes 213 are formed on the side 212.

When the packaged electronic component 2 encounters high temperatures during reflow soldering, heat can be rapidly exhausted through the hole 213. Further, the heated silicon material 23 can expand into the excess space of the holes 213, such that the packaged electronic component 2 does not crack due to thermal expansion of the silicon material 23.

Further, the body 21 can be covered by a heat-conductive clamping element. The heat-conductive clamping element tightly covers the top surface and side surfaces of the body 21 without contacting the pins 24. The heat-conductive clamping element is preferably made of metal with efficient heat-dissipating characteristics, such as copper, whereby heat from the body 21 is transmitted to the exterior through the heat-conductive clamping element during reflow soldering.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A packaged electronic component, comprising:
a plurality of magnetic elements; and
a body covering the magnetic elements;
wherein the body has at least one hole on one side thereof.

2. The packaged electronic component as claimed in claim 1, further comprising a silicon material covering the surfaces of magnetic elements.

3. The packaged electronic component as claimed in claim 1, wherein the body is formed by a molding material.

4. The packaged electronic component as claimed in claim 3, wherein the molding material comprises epoxy resin.

5. The packaged electronic component as claimed in claim 1, wherein the magnetic elements are coils.

6. The packaged electronic component as claimed in claim 1, further comprising a plurality of pins disposed on two opposite sides of the body.

7. The packaged electronic component as claimed in claim 1, wherein the packaged electronic component is a surface mount device.

8. The packaged electronic component as claimed in claim 7, wherein the electronic component is a local area network filter (LAN filter).

9. The packaged electronic component as claimed in claim 1, wherein the body is covered by a heat-conductive clamping element.

10. The packaged electronic component as claimed in claim 9, wherein the heat-conductive clamping element covers a top surface and a side surface of the body.

11. The packaged electronic component as claimed in claim 9, wherein the heat-conductive clamping element is made of metal.

12. The packaged electronic component as claimed in claim 11, wherein the metal is copper.
